(19) United States
(12) Patent Application Publication
(10) Pub. No.: US 2025/0252971 A1
(43) Pub. Date: Aug. 7, 2025

(54) Shunt Reducing Migration Barrier Layer Materials and Insertion Techniques for Epitaxial Topological Materials

(71) Applicant: Western Digital Technologies, Inc., San Jose, CA (US)

(72) Inventors: Quang LE, San Jose, CA (US); Brian R. YORK, San Jose, CA (US); Cherngye HWANG, San Jose, CA (US); Xiaoyong LIU, San Jose, CA (US); Michael A. GRIBELYUK, Stamford, CT (US); Hisashi TAKANO, Fujisawa-shi (JP)

(73) Assignee: Western Digital Technologies, Inc., San Jose, CA (US)

(21) Appl. No.: 19/041,235

(22) Filed: Jan. 30, 2025

Related U.S. Application Data
(60) Provisional application No. 63/627,962, filed on Feb. 1, 2024.

(51) Int. Cl. G11B 5/39; G11B 5/00; G11C 11/16; H10N 50/10; H10N 50/85

(52) U.S. Cl. CPC G11B 5/3909; G11C 11/161; H10N 50/10; H10N 50/85; G11B 2005/0024

(57) ABSTRACT

The present disclosure generally relates to topological insulator (TI) based or topological semi-metal (TSM) based spin-orbit torque (SOT) devices. The SOT device comprises a buffer layer, a first migration barrier layer, a TI or TSM layer, a second migration barrier layer, an interlayer, a ferromagnetic layer, and a capping layer. The TI or TSM layer is disposed in contact with the first and second migration barrier layers. The SOT device can also comprise a buffer layer, a ferromagnetic layer, an interlayer, a first migration barrier layer, a TI or TSM layer, a second migration barrier layer, and a capping layer. The TI or TSM layer is disposed in contact with the first and second migration barrier layers.

### CROSS-REFERENCE TO RELATED APPLICATIONS

This application claims benefit of U.S. provisional patent application Ser. No. 63/627,962, filed Feb. 1, 2024, which is herein incorporated by reference.

### BACKGROUND OF THE DISCLOSURE

### Field of the Disclosure

Embodiments of the present disclosure generally relate to spin-orbit torque (SOT) device comprising a topological insulator (TI) layer or a topological semi-metal (TSM) layer.

### Description of the Related Art

BiSb layers and YPtBi layers are narrow band gap topological insulators and topological semi-metals having both giant spin Hall effect and high electrical conductivity. BiSb and YPtBi are materials that have been proposed in various spin-orbit torque (SOT) device applications, such as for a spin Hall layer for magnetoresistive random access memory (MRAM) devices, magnetic recording read heads, sensors, and energy-assisted magnetic recording (EAMR) magnetic recording heads.

However, utilizing BiSb and/or YPtBi materials in commercial SOT applications can present several obstacles. For example, BiSb materials have low melting points, large grain sizes, significant Sb migration issues upon thermal annealing due to its film roughness, difficulty maintaining a desired (012) or (001) orientation for maximum spin Hall effect, and are generally soft and easily damaged by ion milling. YPtBi materials require specific buffer and/or interlayers to achieve the desired orientation.

Therefore, there is a need for an improved SOT device utilizing TI layer(s) having a desired crystal orientation.

### SUMMARY OF THE DISCLOSURE

The present disclosure generally relates to topological insulator (TI) or topological semi-metal (TSM) based spin-orbit torque (SOT) devices. The SOT device comprises a buffer layer, a first migration barrier layer, a TI or TSM layer, a second migration barrier layer, an interlayer, a ferromagnetic layer, and a capping layer. The TI or TSM layer is disposed in contact with the first and second migration barrier layers. The SOT device can also comprise a buffer layer, a ferromagnetic layer, an interlayer, a first migration barrier layer, a TI or TSM layer, a second migration barrier layer, and a capping layer. The TI or TSM layer is disposed in contact with the first and second migration barrier layers.

In one embodiment, a spin-orbit torque (SOT) device comprises a first migration barrier layer, a topological insulator (TI) or topological semi-metal (TSM) layer disposed on the first migration barrier layer, a second migration barrier layer disposed on the TI or TSM layer, an interlayer disposed on the second migration barrier layer, wherein the first and second migration barrier layers each individually comprises one or more materials selected from a first group, a second group, or a third group, wherein: the first group comprises: RuHf; Zr—X alloys, where X is one or more of Co, Cu, Ru, and Rh; Ti—Y alloys, where Y is one or more of Au, Ru, and Rh; stoichiometric B2 ternary A (BxC1-x) alloys; and alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; the second group comprises: oxides of Ti, Mg, Ni, Zn, or Zr; and X—N or X—C composites where X is one or more of Sc, Ti, V, Cr, Zr, Nb, Ta, Hf, and W; and the third group comprises: tetragonal oxides with a-axis lattice parameters in a range of 4.35 Å to 4.75 Å and c-axis in the range of 2.85 Å to 3.19 Å; MO2, where M is Ti, Cr, Ru, Rh, Sn, Sb, or Ir; and CrNb, CrV, and WV alloys, and a ferromagnetic (FM) layer disposed on the interlayer.

In another embodiment, a spin-orbit torque (SOT) device comprises a ferromagnetic (FM) layer, an interlayer comprising a sub-interlayer disposed on the FM layer, and a first migration barrier layer disposed on the sub-interlayer, a topological insulator (TI) or topological semi-metal (TSM) layer disposed on the first migration barrier layer, and a second migration barrier layer disposed on the TI or TSM layer, the first and second migration barrier layers each individually comprising one or more materials selected from a first group, a second group, or a third group, wherein: the first group comprises: RuHf; Zr—X alloys, where X is one or more of Co, Cu, Ru, and Rh; Ti—Y alloys, where Y is one or more of Au, Ru, and Rh; stoichiometric B2 ternary A (BxC1-x) alloys; and alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; the second group comprises: oxides of Ti, Mg, Ni, Zn, or Zr; and X—N or X—C composites where X is one or more of Sc, Ti, V, Cr, Zr, Nb, Ta, Hf, and W; and the third group comprises: tetragonal oxides with a-axis lattice parameters in a range of 4.35 Å to 4.75 Å and c-axis in the range of 2.85 Å to 3.19 Å; MO2, where M is Ti, Cr, Ru, Rh, Sn, Sb, or Ir; and CrNb, CrV, and WV alloys.

In yet another embodiment, a spin-orbit torque (SOT) device comprises a first migration barrier layer, a topological insulator (TI) or topological semi-metal (TSM) layer disposed in contact with the first migration barrier layer, the TI or TSM layer comprising YPtBi having a (100) orientation, YPtBi having a (110) orientation, or BiSb having a (012) orientation, a second migration barrier layer disposed in contact with the TI layer, the first and second migration barrier layers each individually comprising one or more materials selected from a first group, a second group, or a third group, wherein: the first group comprises: RuHf; Zr—X alloys, where X is one or more of Co, Cu, Ru, and Rh; Ti—Y alloys, where Y is one or more of Au, Ru, and Rh; stoichiometric B2 ternary A (BxC1-x) alloys; and alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; the second group comprises: oxides of Ti, Mg, Ni, Zn, or Zr; and X—N or X—C composites where X is one or more of Sc, Ti, V, Cr, Zr, Nb, Ta, Hf, and W; and the third group comprises: tetragonal oxides with a-axis lattice parameters in a range of 4.35 Å to 4.75 Å and c-axis in the range of 2.85 Å to 3.19 Å; MO2, where M is Ti, Cr, Ru, Rh, Sn, Sb, or Ir; and CrNb, CrV, and WV alloys, and a ferromagnetic (FM) layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a magnetic recording head having a SOT MTJ device.

FIG. 2 is a fragmented, cross-sectional side view of certain embodiments of a read/write head having a SOT MTJ device.

FIGS. 3A-3B illustrate spin orbit torque (SOT) devices, according to various embodiments.

FIG. 4 illustrates the first and/or second migration barrier layer of FIGS. 3A-3B, according to one embodiment.

FIG. 5A is a schematic cross-sectional view of a SOT device for use in a MAMR magnetic recording head, such as the MAMR magnetic recording head of the drive of FIG. 1 or other suitable magnetic media drives.

FIGS. 5B-5C are schematic MFS views of certain embodiments of a portion of a MAMR magnetic recording head with a SOT device of FIG. 5A.

FIG. 6 is a schematic cross-sectional view of an MRAM device according to one embodiment, which has a top SOT stack configuration.

FIG. 7 is a schematic cross-sectional view of another MRAM device according to one embodiment, which has a bottom SOT stack configuration, with a TI or TSM bottom layer below the MTJ, in contrast to the top SOT stack configuration of FIG. 6.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to topological insulator (TI) or topological semi-metal (TSM) based spin-orbit torque (SOT) devices. The SOT device comprises a buffer layer, a first migration barrier layer, a TI or TSM layer, a second migration barrier layer, an interlayer, a ferromagnetic layer, and a capping layer. The TI or TSM layer is disposed in contact with the first and second migration barrier layers. The SOT device can also comprise a buffer layer, a ferromagnetic layer, an interlayer, a first migration barrier layer, a TI or TSM layer, a second migration barrier layer, and a capping layer. The TI or TSM layer is disposed in contact with the first and second migration barrier layers. TI or TSM layer 312

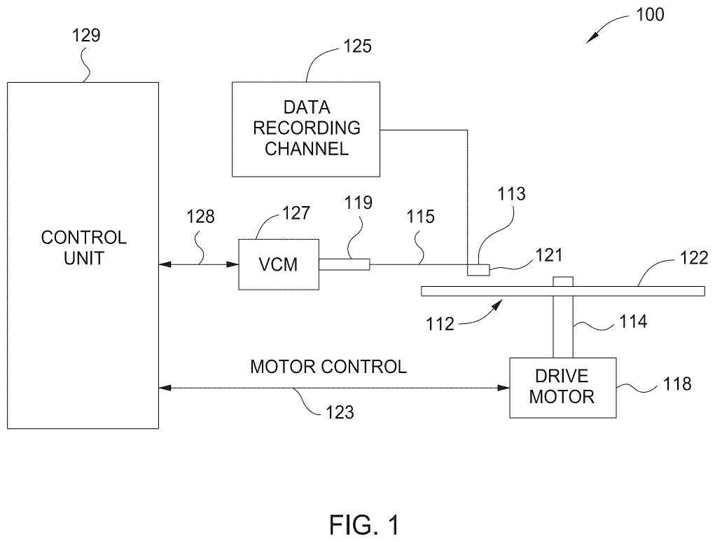

FIG. 1 is a schematic illustration of certain embodiments of a magnetic media drive 100 including a magnetic recording head having a SOT MTJ device. Such a magnetic media drive may be a single drive or comprise multiple drives. For the sake of illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

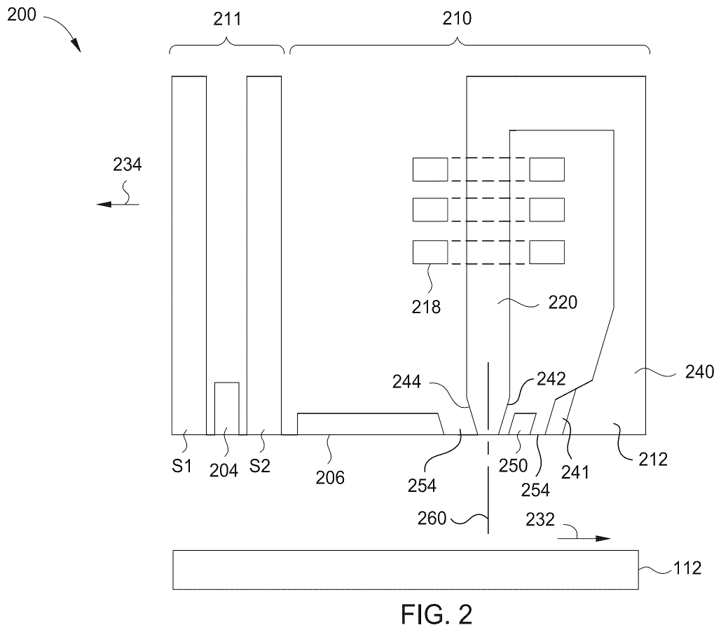

At least one slider 113 is positioned near the magnetic disk 112, each slider 113 supporting one or more magnetic head assemblies 121 that include a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by way of a suspension 115. The suspension 115 provides a slight spring force which biases the slider 113 toward the disk surface 122. Each actuator arm 119 is attached to an actuator means 127. The actuator means 127 as shown in FIG. 2 may be a voice coil motor (VCM). The VCM includes a coil movable within a fixed magnetic field, the direction and speed of the coil movements being controlled by the motor current signals supplied by control unit 129.

During operation of the disk drive 100, the rotation of the magnetic disk 112 generates an air bearing between the slider 113 and the disk surface 122 which exerts an upward force or lift on the slider 113. The air bearing thus counter-balances the slight spring force of suspension 115 and supports slider 113 off and slightly above the disk surface 122 by a small, substantially constant spacing during normal operation.

The various components of the disk drive 100 are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads on the assembly 121 by way of recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232 and the read/write head 200 moves in the direction indicated by the arrow 234.

In some embodiments, the magnetic read head 211 is a magnetoresistive (MR) read head that includes an MR sensing element 204 located between MR shields S1 and S2. In other embodiments, the magnetic read head 211 is a magnetic tunnel junction (MTJ) read head that includes a MTJ sensing device 204 located between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of an SOT read head is described in co-pending patent application titled “Topological Insulator Based Spin Torque Oscillator Reader,” U.S. application Ser. No. 17/828,226, filed May 31, 2022, assigned to the same assignee of this application, which is herein incorporated by reference. Another example of an SOT read head is described in co-pending patent applications titled “Non-Localized Spin Valve Reader Hybridized With Spin Orbit Torque Layer,” U.S. application Ser. No. 18/367,877, filed Sep. 13, 2023, and “Non-Localized Spin Valve Multi-Free-Layer Reader Hybridized With Spin Orbit Torque Layers,” U.S. application Ser. No. 18/367,882, filed Sep. 13, 2023, both of which are herein incorporated by reference.

The write head 210 includes a main pole 220, a leading shield 206, a trailing shield 240, an optional spin orbital torque (SOT) device 250, and a coil 218 that excites the main pole 220. The coil 218 may have a “pancake” structure which winds around a back-contact between the main pole 220 and the trailing shield 240, instead of a “helical” structure shown in FIG. 2. When included, e.g., to achieve a Microwave Assisted Magnetic Recording (MAMR) effect, the SOT device 250 is formed in a gap 254 between the main pole 220 and the trailing shield 240. The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may be a magnetic material, such as a NiFe alloy. In certain embodiments, the trailing shield 240 can include a trailing shield hot seed layer 241. The trailing shield hot seed layer 241 can include a high moment sputter material, such as CoFeN, FeXN, or FeX, where X includes at least one of N, AI, Ni, Co, Ta, Re, Ir, Pt, Rh, Ta, Zr, and Ti. In certain embodiments, the trailing shield 240 does not include a trailing shield hot seed layer. In other embodiments, instead of an SOT device 250 it may be a conductive stack in the write gap. In certain embodiments, the read/write head 200 additionally includes mechanisms (not shown) for supporting Heat Assisted Magnetic Recording (HAMR), which may include a waveguide coupled to a light source and a near field transducer (NFT) placed adjacent to the main pole 220 and coupled to the waveguide to convert the delivered light into a heating spot on the media.

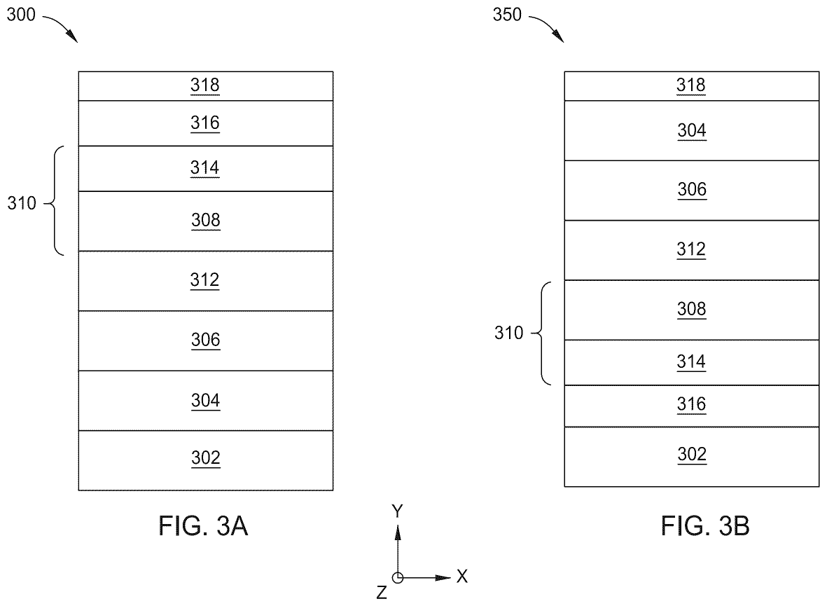

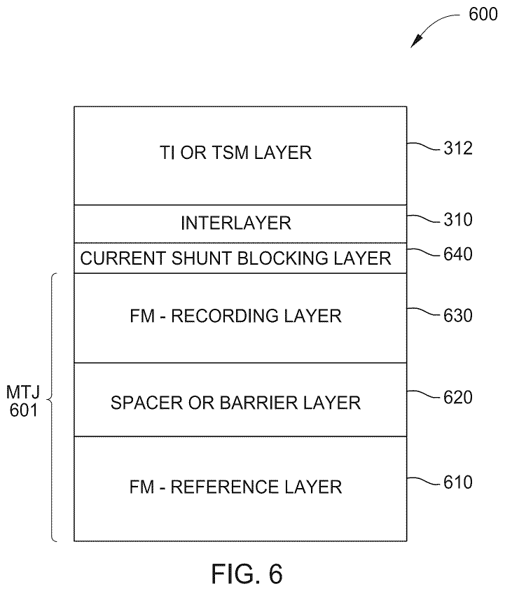

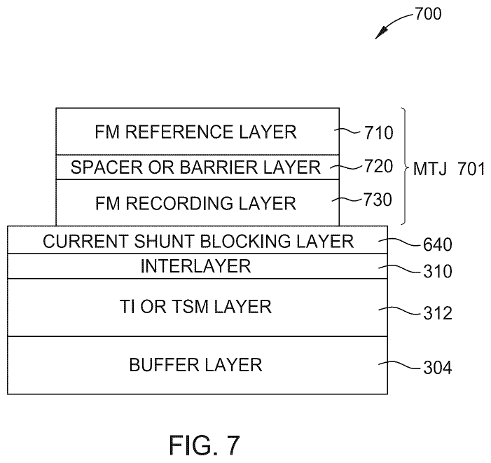

FIGS. 3A-3B illustrate spin-orbit torque (SOT) devices 300, 350, according to various embodiments. The SOT devices 300, 350 may each individually be used in the MAMR recording head of the drive 100 of FIG. 1, in the reader, and/or writer portions of the head 200 of FIG. 2, or other suitable magnetic media drives. The SOT devices 300, 350 may each individually be an MTJ in sensors or used in MRAM applications, such as the example MRAM embodiments disclosed in FIGS. 6 and 7, and spin-charge conversion layers/structures in logic circuit that can be used as neuromorphic, neuron elements or other machine learning/computational elements as part of artificial intelligence chips. Other applications include magnetic sensors via a direct or indirect spin Hall effect, and spin Hall oscillators. Aspects of the SOT devices 300, 350 may be used in combination with one another.

The SOT device 300 of FIG. 3A comprises a seed layer 302, a buffer layer 304 disposed over the seed layer 302, a first migration barrier layer 306 disposed over the buffer layer 304, a topological insulator (TI) or topological semi-metal (TSM) layer 312 disposed on the first migration barrier layer 306, an interlayer 310 disposed on the TI or TSM layer 312, a ferromagnetic (FM) layer 316 disposed on the interlayer 310, and a cap layer 318 disposed on the FM layer 316. The interlayer 310 comprises a second migration barrier layer 308 disposed on the TI or TSM layer 312, and a sub-interlayer 314 disposed on the second migration barrier layer 308. The first migration barrier layer 306 may comprise a different material than the second migration barrier layer 308. In some embodiments, the second migration barrier layer 308 and the sub-interlayer 314 are considered separate layers, rather than as an interlayer 310. The buffer layer 304 may have a (100) orientation, a (110) orientation, or a (012) orientation.

The SOT device 350 of FIG. 3B comprises the seed layer 302, the FM layer 316 disposed on the seed layer 302, the interlayer 310 disposed on the FM layer 316, the TI or TSM layer 312 disposed on the interlayer 310, the first migration barrier layer 306 disposed on the TI or TSM layer 312, the buffer layer 304 disposed on the first migration barrier layer 306, and the cap layer 318 disposed on the buffer layer 304. The interlayer 310 comprises the sub-interlayer 314 disposed on the FM layer 316, and the second migration barrier layer 308 disposed between the sub-interlayer 314 and the TI or TSM layer 312. The first migration barrier layer 306 may comprise a different material than the second migration barrier layer 308. The sub-interlayer 314 may have a (100) orientation, a (110) orientation, or a (012) orientation.

In both SOT devices 300, 350, the first and second migration barrier layers 306, 308 are disposed in contact with the TI or TSM layer 312 such that the TI or TSM layer 312 is sandwiched between the first and second migration barrier layers 306, 308. The buffer layer 304, the interlayer 310, and the cap layer 318 promote epitaxial crystal symmetry growth of the TI or TSM layer 312 while minimizing shunting. The migration barrier layers 306, 308 further transmit the epitaxial growth and, due to minimal chemical interaction, prevent diffusion of the TI or TSM layer 312 out and prevent materials from diffusing into the TI or TSM layer 312 from the buffer layer 304, the interlayer 310, and the cap layer 318. The TI or TSM layer 312 comprises YPtBi having a (100) orientation or a (110) orientation, or BiSb having a (012) orientation. In some embodiments, the TI or TSM layer 312 comprises doped BiSb, such as BiSbGe. The TI or TSM layer 312 has a thickness in the y-direction of about 100 Å to about 140 Å, such as about 120 Å.

The first migration barrier layer 306 may comprise a different material than the second migration barrier layer 308. The first and second migration barrier layers 306, 308, are not only effective at reducing elemental migration but are generally higher resistance layers which reduce electrical shunting between layers and serve to transfer the (100) or (110) epitaxial growth from one layer to the next, or to the topological SOT layers which lowers interfacial roughness. Barrier layers can be selected from 3 different nonmagnetic type material groups.

The first group of materials for the barrier layers 306, 308 includes these options: (1) high lattice parameter, higher resistance, atomically ordered stoichiometric B2 (AB) binary alloys, such as RuHf and Zr—X alloys, where X is one or more of Co, Cu, Ru, and Rh; (2) Ti—Y alloys, where Y is one or more of Au, Ru, and Rh; or (3) stoichiometric B2 ternary A(BxC1-x) alloys, like (HfTi).5Ru, Ru(AIV).5, (AIMo).5Ti, and CoZrX, where X is one or more of Ti, Fe, Ni, Nb, and Mo (examples include (Co(Ti.3Zr.7), (Co.8Fe.2)Zr, (CoNi).5Zr, Co(Nb.25Zr.75). The barrier layers 306, 308 can also be disordered nonstoichiometric binary, ternary, or higher bcc alloys where multiple elements are selected, to form a bcc alloy, from the group consisting of: Ta, Hf, W, Ir, Pt, Y, Zr, Nb, Mo, Mg, Sc, Ti, V, Cr, Fe, Co, Ni, Cu, Ru, Rh, and Ag, where all have lattice parameters in the range of 2.87 Å to 3.38 Å.

The second group of materials for the barriers layers 306, 308 are fcc materials with lattice parameters about 4.08 Å to 4.75 Å, such as oxides of Ti, Mg, Ni, Zn, or Zr; or X—N or X—C composites where X is one or more of Sc, Ti, V, Cr, Zr, Nb, Ta, Hf, and W, as well as alloy composites of the above.

The third group of materials for the barrier layers 306, 308 are tetragonal oxides with a-axis lattice parameters in a range of 4.35 Å to 4.75 Å and c-axis in the range of 2.85 Å to 3.19 Å, like MO₂ materials, examples of which include where M is Ti, Cr, Ru, Rh, Sn, Sb, or Ir; or CrNb, CrV, and WV alloys; or any combination thereof.

The first two barrier layer material groups can be used with either (100) or (110) texturing layers to form (100) or (110) textured barrier layers 306, 308. The texturing of the third group of barrier layer materials (i.e., the MO₂ tetragonal oxides) will depend on the texturing layer type. For (100) texturing layers, the MO₂ tetragonal oxides will produce (001) textured MO₂ tetragonal oxides, which in turn can be used to create (100) texture in other layers. With (110) texturing layers, the MO₂ tetragonal oxides will create a (110) textured tetragonal M0₂ oxide layer, but only for oxides where the a/c ratio is near the sqrt(2), such as where M is Os, Ir, Ru, Rh, or Pd. The first migration barrier layer 306 may comprise a different material than the second migration barrier layer 308. Each barrier layer 306, 308 may comprise one or more barrier layers depending on the application to optimize growth, electrical shunting, or elemental migration properties between layers.

The seed layer 302 comprises an amorphous or nanocrystalline material. The seed layer 302 may comprises a laminated structure comprising one or more materials selected from the group consisting of NiTa, RuAl, MgO, MgTiO, CrMo, CoFeTa, NiFeGe, NiFeTa, NiW, Ru, IrAl, and combinations thereof. The seed layer 302 has a thickness in the y-direction of about 10 Å to about 30 Å, such as about 20 Å.

The buffer layer 304 may comprise a combination of materials selected from the groups consisting of (100) or (110) textured layers, or mixtures thereof, with the groups of (a)-(k) listed below: (a) bcc metals or alloys with a-axis lattice parameters in the range of 2.9 Å to about 3.4 Å, such as Ta, W, Mo, Nb, WTi, and CrMo; (b) B2 metals with the same lattice parameter range, such as binary alloys of RuAl, RuHf, Zr—X alloys, where X is one or more of Co, Cu, Ru, and Rh, or Ti—Y alloys where Y is one or more of Au, Ru, and Rh; (c) B2 ternary alloys like HfRuTi, RuAIV, AITiMo, and CoZrX, where X is one or more of Ti, Fe, Ni, Nb, and Mo, or any combinations of the above; (d) (100) and (110) textured fcc materials with lattice parameters about 4.08 Å to about 4.75 Å, such as oxides of Ti, Mg, Ni, Zn, and Zr, X—N, or X—C composites, where X is one or more of Sc, Ti, V, Cr, Zr, Nb, Ta, Hf, and W, as well as alloy composites of the above; (e) (001) textured tetragonal oxides with a-axis lattice parameters in a similar range as above, such as MO₂ materials, where M is one or more of Ti, Cr, Ru, Rh, Sn, Sb, and Ir, or alloy composites thereof; (f) (110) textured tetragonal MO₂ where a/c ratio is near the sqrt(2), such as where M is one or more of Os, Ir, Ru, Rh, Sn, Sb, and Pd; (g) high lattice parameter fcc (110) or (100) textured Heusler alloys, either half metallic or full, with lattice parameters in the range of 5.9 Å to 6.7 Å, such as MnSbPt (6.20 Å) or Sc₂VGe (a=6.65 Å), and Pd₂SnY (6.70 Å); (h) other spinel cubic materials with the space group 216 and similar lattice parameters, such as YNiBi, YPdBi, NiBiGd, AgMgSb, and BiXPt (where X is a rare earth element from Gd to Lu); (i) (100) textured layer materials such as X—Al, where X is one or more of Co, Ni, Ru, Rh, and Ir; (j) heated Cr or CrX alloys, where X is one or more of Mo, Mn, Ti, Ru, and W; and (k) combinations thereof.

Those skilled in the art can grow bcc metals along the close-packed direction creating strong (110) textured bcc or bcc alloy films mentioned above with lattice parameters in the range of 2.9 Å to 3.4 Å range, using combinations of nanocrystalline conditioning layers and other bcc seed layer materials; alloys seed layer films, such as the Cr—X alloys mentioned above; or by using thin (001) hcp Ru seeds. These highly textured (110) bcc or bcc alloy films can then be used to grow fcc (110) textured buffer layer films with lattice parameters of about 4.08 Å to 4.75 Å mentioned; (110) textured binary or ternary or higher B2 alloys mentioned above; or high lattice parameter fcc Heuslers or spinels with lattice parameters in the range of about 5.9 Å to 6.7 Å mentioned above, which can be utilized as high resistance or migration buffers layers on which to grow (110) textured YPtBi SOT layers. (110) textured buffer layers of MO₂ oxides could also be used for those oxides that have a/c ratios near the sqrt(2), as mentioned above.

Those skilled in the art can also grow bcc metals or B2 materials and alloys with a strong (100) texture and lattice parameters in the range of about 2.9 Å to 3.4 Å like those of RuAl or heated Cr—X alloys mentioned above. These (100) textured layers can be used to grow strong fcc (100) textured buffer layers with lattice parameters in the range of 4.08 Å to 4.75 Å mentioned above; (100) textured Heusler alloys or spinel type structures with lattice parameters in the range of 5.9 Å to 6.75 Å mentioned above; or (001) textured MO2 tetragonal oxides mentioned above with axis lattice parameters in the 4.1 Å to 4.75 Å range.

Buffer layers between the textured seed layers and the SOT layer can, in general, offer better control of electrical shunting between the seed layers and the SOT layer, or serve as migration barriers to prevent intermixing of the SOT layer and seed layers, or provide better film epitaxial growth to the YPtBi or BiSbX SOT layer.

In order to grow epitaxially strong (012) textured BiSbX SOT layers, (110) textured seed layers or buffer layers are not useful for: BiSbX SOT layers that require (100) textured seed layers; fcc buffer layers which are in the lower a-axis range 4.08 Å to about 4.6 Å, bcc or B2 alloys having an a-axis range around 2.9 Å to about 3.2 Å for; fcc Heuslers or spinels with lattice parameters in the range of about 5.9 Å to about 6.4 Å; or (001) MO₂ oxides mentioned above with a-axis below about 4.5 Å. The (100) textured seed layers and buffers layers serve the same purpose as mentioned above for YPtBi SOT layers, to better control electrical shunting and elemental intermixing between the seed or buffer layers and to provide potentially better epitaxial growth of BiSbX SOT layers.

High resistance binary or ternary or higher B2 alloy buffer layers offer additional manufacturability options to fcc buffer layers to improve epitaxial growth and impede migration or reduce shunting of seed layers, buffer layers, FM layers, and the SOT layers, or between the SOT layer and the FM layer or capping layers. The buffer layer 304 has a thickness in the y-direction of about 30 Å to 50 Å.

The FM layer 316 has a thickness of about 5 Å to about 15 Å, and may comprise NiFe, CoFe, NiFeX, CoFex, FeX, or NiX, where X is one or more of Co, Ni, Cu, Si, Al, Mn, Ge, Ta, Hf, N, or B. The FM layer 316 may comprise any magnetic layer combination or alloy combination of these elements that can yield a low coercivity, negative magnetostrictive FM layer 316, or in multilayer combinations with other higher polarizing materials like Heusler alloys or high Ni containing alloy FM layers. The sub-interlayer 314 may comprise MgO, CoFeB, Co, CoFe, NiFe, or a similar material as the FM layer 316. The sub-interlayer 314 and the interlayer 310 collectively have a thickness in the y-direction of about 20 Å or less.

The cap layer 318 may comprise non-magnetic, high resistivity materials, such as: thin ceramic oxides or nitrides of TIN, SiN, MgTiO, and MgO; amorphous/nanocrystalline metals such as NiFeGe, NiFeTa, NiTa, NiHf, NiFeHf, CoHf, CoFeHf, NiWTa, NiFeW, NiW, WRe; or nitrides, oxides, or borides of above-mentioned elements, compounds, and/or alloys such as NiTaN, NiFeTaN, NiWTaN, NiWN, WREN, TaN, WN, TaOx, WOx, WB, HfB, NiHfB, NiFeHfB, CoHfB, and CoFeHfB, where x is a numeral. In some embodiments, lower atomic number (Z) materials are preferred in the cap layer 318 to reduce sputter intermixing with the FM layer 316, but high Z alloys can be used, if used in combination with a migration barrier beneath, or if the high Z elements are used with a high resistive oxide, nitride, or boride. The cap layer 318 can comprise multilayer combinations of the above-mentioned materials, and the overall thickness of the cap layer 318 is less than or equal to about 100 Å (nominally about 15 Å to about 50 Å).

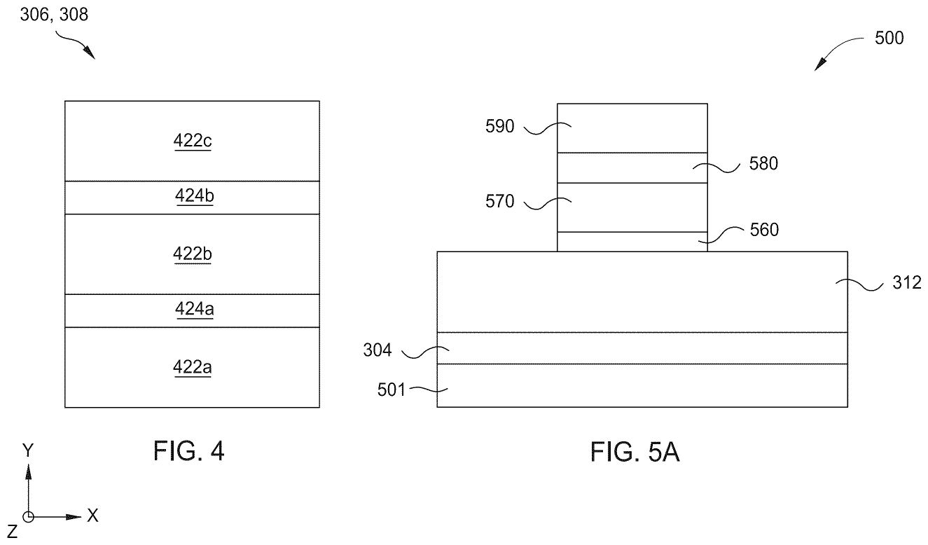

FIG. 4 illustrates the first and/or second migration barrier layer(s) 306, 308 of FIGS. 3A-3B, according to one embodiment. The first and/or second migration barrier layers 306, 308 are alloyed with the material of the TI or TSM layer 312 (i.e., YBiPt or BiSb) through doping and/or lamination. For example, the first and/or second migration barrier layers 306, 308 may comprise one or more migration barrier sub-layers 422a, 422b, 422c, alternatingly laminated or doped with the layers 424a, 424b comprising the material of the TI layer. The one or more migration barrier sub-layers 422a, 422b, 422c may comprise W, WTi, WNb, WV, WTa, NiCu, Ni, NiW, or a combination thereof. By laminating and/or doping the first and/or second migration barrier layers 306, 308 with the material of the TI or TSM layer 312, diffusion of materials into the TI or TSM layer 312 or from the TI or TSM layer 312 to other layers of the SOT stack is further prevented.

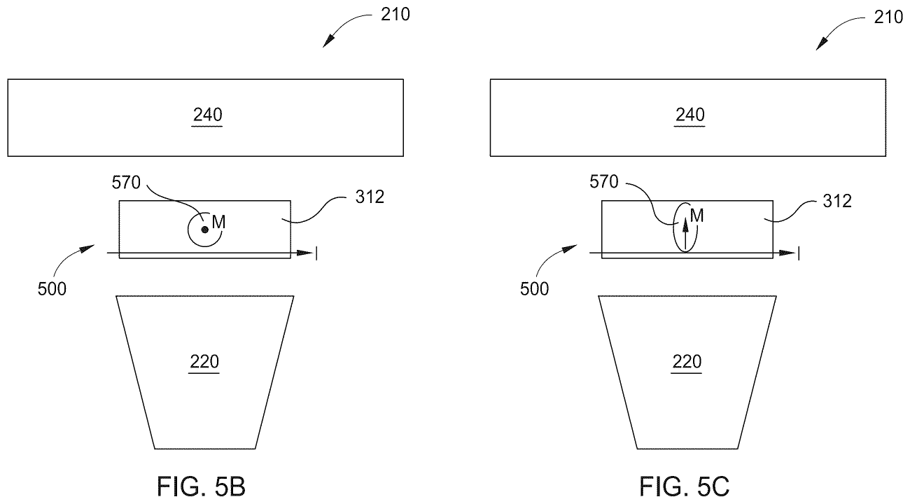

FIG. 5A is a schematic cross-sectional view of a SOT device 500 for use in a MAMR magnetic recording head, such as the MAMR magnetic recording head of the drive 100 of FIG. 1 or other suitable magnetic media drives. The SOT device 500 comprises a TI or TSM layer 312 orientation formed over a buffer layer 304 formed over a substrate 501, such as the TI or TSM layer 312 and the buffer layer 304 of FIG. 3A or the TI or TSM layer 312 and the buffer layer 304 of FIG. 3B. Thus, the TI or TSM layer 312 may comprise YPtBi having a (100) orientation, YPtBi having a (110) orientation, or BiSb having a (012) orientation. A spin torque layer (STL) 570 is formed over the TI or TSM layer 312. The STL 570 comprises a ferromagnetic material such as one or more layers of CoFe, Colr, NiFe, and CoFeX alloy wherein X=B, Ta, Re, or Ir.

In certain embodiments, an electrical current shunt blocking layer 560 is disposed between the TI or TSM layer 312 and the STL 570. The electrical current shunt blocking layer 560 reduces electrical current from flowing from the TI or TSM layer 312 to the STL 570 but allows spin orbital coupling of the TI or TSM layer 312 and the STL 570. In certain embodiments, the electrical current shunt blocking layer 560 comprises a magnetic material which provides greater spin orbital coupling between the TI or TSM layer 312 and the STL 570 than a non-magnetic material. In certain embodiments, the electrical current shunt blocking layer 560 comprises a magnetic material of FeCo, FeCOM, FeCOMO, FeCoMMeO, FeCOM/MeO stack, FeCoMNiMnMgZnFeO, FeCOM/NiMnMgZnFeO stack, multiple layers/stacks thereof, or combinations thereof in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr. In certain embodiments, the electrical current shunt blocking layer 560 is formed to a thickness from about 10 Å to about 100 Å. In certain aspects, an electrical current shunt blocking layer 560 having a thickness of over 100 Å may reduce spin orbital coupling of the TI or TSM layer 312 and the STL 570. In certain aspects, an electrical current shunt blocking layer having a thickness of less than 10 Å may not sufficiently reduce electrical current from TI or TSM layer 312 to the STL 570.

In certain embodiments, additional layers are formed over the STL 570 such as a spacer layer 580 and a pinning layer 590. The pinning layer 590 can partially pin the STL 570. The pinning layer 590 comprises a single or multiple layers of PtMn, NiMn, IrMn, IrMnCr, CrMnPt, FeMn, other antiferromagnetic materials, or combinations thereof. The spacer layer 580 comprises single or multiple layers of magnesium oxide, aluminum oxide, other non-magnetic materials, or combinations thereof.

FIGS. 5B-5C are schematic MFS views of certain embodiments of a portion of a MAMR magnetic recording head 210 with a SOT device 500 of FIG. 5A. The MAMR magnetic recording head 210 can be the magnetic recording head FIG. 2 or other suitable magnetic recording heads in the drive 100 of FIG. 1 or other suitable magnetic media drives such as tape drives. The MAMR magnetic recording head 210 includes a main pole 220 and a trailing shield 240 in a track direction. The SOT device 500 is disposed in a gap between the main pole and the trailing shield 240.

While the MRAM device 500 generally corresponds to the top-SOT embodiments of FIG. 3B, other MRAM implementations (where the layers of MRAM device 500 are reversed) can correspond to the bottom-SOT embodiments of FIG. 3A. The TI or TSM layer 312, the RL 510, and the buffer layer 302 in FIG. 5 may correspond to various layer configurations in FIGS. 3A-3B. For example, the TI or TSM layer 312 can correspond to the TI or TSM layer 312. Thus, the TI or TSM layer 312 may comprise YPtBi having a (100) orientation, YPtBi having a (110) orientation, or BiSb having a (012) orientation. The RL 510 may correspond to the FM layer 316. The buffer layer 302 may correspond to the barrier layer 314 and the cap layer 318.

During operation, charge current through a TI layer or layer stack 312 acting as a spin Hall layer generates a spin current in the BiSb layer. The spin orbital coupling of the BiSb layer and a spin torque layer (STL) 570 causes switching or precession of magnetization of the STL 570 by the spin orbital coupling of the spin current from the TI or TSM layer 312. Switching or precession of the magnetization of the STL 570 can generate an assisting AC field to the write field. Energy assisted magnetic recording heads based on SOT have multiple times greater power efficiency in comparison to MAMR magnetic recording heads based on spin transfer torque. As shown in FIG. 5B, an easy axis of a magnetization direction of the STL 570 is perpendicular to the MFS from shape anisotropy of the STL 570, from the pinning layer 590 of FIG. 5A, and/or from hard bias elements proximate the STL 570. As shown in FIG. 5C, an easy axis of a magnetization direction of the STL 570 is parallel to the MFS from shape anisotropy of the STL 570, from the pinning layer 590 of FIG. 5A, and/or from hard bias elements proximate the STL 570.

FIGS. 6 and 7 show a top SOT MRAM device and a bottom SOT MRAM device, respectively, according to various embodiments.

FIG. 6 is a schematic cross-sectional view of a magnetic tunnel junction (MTJ) 601 used as a top SOT MRAM device 600, according to one embodiment. The MRAM device 600 comprises an MTJ 601, which includes a ferromagnetic (FM) reference layer (RL) 610, a spacer or barrier layer 620 over the RL 610, and an FM recording layer 630 over the spacer or barrier layer 620. In addition, the MRAM device 600 comprises an interlayer 310 over an electrical current shunt blocking layer 640 over the recording layer 630 of the MTJ 601, and a TI or TSM layer stack 312 over the interlayer 310. The TI or TSM layer 312 and the interlayer 310 may be the TI or TSM layer 312 and the interlayer 310 of FIG. 3B.

Like in FIG. 3B, the interlayer 310 comprises the second migration barrier layer 308 and the sub-interlayer 314, with their respective material options mentioned above. In addition, the interlayer 310 may comprise the options of MgO and NiFeGe (e.g., layer may comprise MgO or NiFeGe). It may also include the material options for the buffer layer as noted above. The interlayer provides a means to transfer the material structure symmetry from the underlying layers of the MTJ to the TI or TSM layer. This is in contrast to the buffer layer used in FIG. 7, which is necessary to set the material structure and grow the TI or TSM layer in the bottom SOT configuration. Thus, the TI or TSM layer 312 may comprise YPtBi having a (100) orientation, YPtBi having a (110) orientation, or BiSb having a (012) orientation. In addition, the FM recording layer 630 corresponds to the FM layer 316 in FIG. 3B. Other layers such as the seed or cap layer in FIG. 3B above may be optionally included here but not shown.

The RL 610 comprises single or multiple layers of CoFe, other ferromagnetic materials, and combinations thereof. The spacer or barrier layer 620 comprises single or multiple layers of magnesium oxide (MgO), aluminum oxide, other dielectric materials, or combinations thereof. The recording layer 630 comprises single or multiple layers of CoFe, NiFe, other ferromagnetic materials, or combinations thereof, or may comprise material options noted above for the FM layer 316.

As noted above, in certain embodiments, the electrical current shunt blocking layer 640 is disposed between the interlayer 310 and the recording layer 630. The electrical current shunt blocking layer 640 reduces electrical current from flowing from the TI or TSM layer 312 to the recording layer 630 but allows spin orbital coupling of the TI or TSM layer 312 and the recording layer 630. For example, writing to the MRAM device can be enabled by the spin orbital coupling of the TI layer and the recording layer 630, which enables switching of magnetization of the recording layer 630 by the spin orbital coupling of the spin current from the TI or TSM layer 312. In certain embodiments, the electrical current shunt blocking layer 640 comprises a magnetic material which provides greater spin orbital coupling between the TI or TSM layer 312 and the recording layer 630 than a non-magnetic material. In certain embodiments, the electrical current shunt blocking layer 640 comprises a magnetic material of FeCOM, FeCOMO, FeCoMMeO, FeCOM/MeO stack, FeCoMNiMnMgZnFeO, FeCOM/NiMnMgZnFeO stack, multiple layers/stacks thereof, or combinations thereof, in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr.

The MRAM device 600 of FIG. 6 may include other layers, such as pinning layers, pinning structures (e.g., a synthetic antiferromagnetic (SAF) pinned structure), electrodes, gates, and other structures. It is noted that, in other embodiments, the MRAM device may include the TI or TSM layer 312 at the bottom of the stack.

FIG. 7 is a schematic cross-sectional view of another MRAM device 700 according to one embodiment, which has a bottom SOT stack configuration, with a TI or TSM bottom layer below the MTJ, in contrast to the top SOT stack configuration of FIG. 6.

As illustrated in FIG. 7, the MRAM device 700 includes a buffer layer 304, a TI or TSM layer or layer 312 over the buffer layer 304, an interlayer 310 over the TI or TSM layer 312, an electrical current shunt blocking layer 640 over the interlayer 310, and an MTJ 701 over the electrical current shunt blocking layer 640. The MTJ 701 includes an FM recording layer 730, a spacer or barrier layer 720 over the FM recording layer 730, and an FM reference layer (RL) 710 over the spacer or barrier layer 720.

The TI or TSM layer 312 and the buffer layer 304 may be the TI or TSM layer 312 and the buffer layer 304 of FIG. 3A. Thus, the TI or TSM layer 312 may comprise YPtBi having a (100) orientation, YPtBi having a (110) orientation, or BiSb having a (012) orientation. The interlayer 310 corresponds that in FIG. 3A. Like in FIG. 3A, the interlayer 310 comprises the second migration barrier layer 308 and the sub-interlayer 314, with their respective material options mentioned above. In addition, the interlayer 310 may comprise the options of MgO and NiFeGe (e.g., layer may comprise MgO or NiFeGe). It may also include the material options for the buffer layer as noted above. In addition, the recording layer 730 corresponds to the FM layer 316 in FIG. 3A. The layers of the MTJ and the electrical current shunt blocking layer of FIG. 7 otherwise correspond to those of FIG. 6 and may comprise the above described material options. Other layers such as the seed or cap layer in FIG. 3A above may be optionally included here but not shown. Like in FIG. 6, the MRAM device 700 of FIG. 7 may include other layers, such as pinning layers, pinning structures (e.g., a synthetic antiferromagnetic (SAF) pinned structure), electrodes, gates, and other structures.

Generally speaking, in either of the MRAM device 600 or 700, the TI or TSM layer 312 serves as a spin injection source to write data in the MRAM device, whereby a current flowing in a plane of the TI or TSM layer causes a spin current in a direction perpendicular to the plane. Then, the spin current causes switching of the magnetic orientation of the recording layer 630 or 730, reflecting storage of a data bit. The magnetic orientation of the recording layer 630 or 730 relative to that of the reference layer 610 or 710 determines the resistance of the MTJ 601 or 701, enabling the read out of that stored data bit value. The MRAM device 600 or 700 may be implemented as a two or three terminal device.

In certain embodiments, the MRAM device 600 or 700 may be configured as part of a neuromorphic array, through which individual MRAM devices are configured to store weights for machine learning computational purposes (e.g., multiply-accumulate operations). An example of such an array is disclosed in co-pending application titled “Matrix-Vector Multiplication Using SOT-based Non-Volatile Memory Cells,” U.S. application Ser. No. 17/172,155, filed Feb. 10, 2021, the disclosure of which is hereby incorporated by reference. In other embodiments, the material stack configurations of FIGS. 6 and 7 may be part of a spin Hall oscillator instead of an MRAM device, where the recording layer 610 or 710 becomes instead a spin oscillator layer. It is caused to precess by the spin current from the TI or TSM layer 312. A controlled current source into the TI or TSM layer enables control of the oscillation from the spin Hall oscillator device. The mechanism is similar to the MAMR recording head embodiment of FIGS. 5A-5C described above.

In other embodiments, the SOT device of FIGS. 3A-3B are embodied in other applicable spin-to-charge or charge-to-spin conversion use cases. As an example, they can be used in machine learning applications such as those disclosed in co-pending application titled “Spin Orbital Squared (SO-SO) Logic,” U.S. application Ser. No. 18/645,189, filed Apr. 24, 2024, co-pending application titled “Deep Neural Network Device Based on Dual Spin Orbit Torque (SOT) Devices,” U.S. application Ser. No. 18/645,195, filed Apr. 24, 2024, and co-pending application titled “In-Memory Deep Neural Network Device Using Spin Orbit Torque (SOT) With Multi-State Weight,” U.S. application Ser. No. 18/954,415, filed Nov. 20, 2024, the disclosures of which are hereby incorporated by reference. As another example, they can be used in magnetic sensing applications such as those disclosed in co-pending application titled “Magnetic Sensor Half-Bridge Based on Inverse Spin Hall Effect with Reduced Thermal Drift,” U.S. application Ser. No. 18/545,847, filed Dec. 19, 2023, and co-pending application titled “Sensor based on Direct Spin Hall Effect,” U.S. application Ser. No. 18/666,543, filed May 16, 2024, the disclosures of which are hereby incorporated by reference.

Therefore, by sandwiching the TI or TSM layer between two migration barrier layers, the epitaxial growth of the barrier layer and/or interlayers can be transferred to the TI or TSM layer, due to minimal chemical interaction, while further preventing diffusion of the TI or TSM layer out into other layers and preventing materials from diffusing into the TI or TSM layer. As such, the migration barrier layers promote epitaxial crystal symmetry growth of the TI or TSM layer while minimizing shunting of the SOT device.

In one embodiment, a spin-orbit torque (SOT) device comprises a first migration barrier layer, a topological insulator (TI) or topological semi-metal (TSM) layer disposed on the first migration barrier layer, a second migration barrier layer disposed on the TI or TSM layer, an interlayer disposed on the second migration barrier layer, wherein the first and second migration barrier layers each individually comprising one or more materials selected from a first group, a second group, or a third group, wherein: the first group comprises: RuHf; Zr—X alloys, where X is one or more of Co, Cu, Ru, and Rh; Ti—Y alloys, where Y is one or more of Au, Ru, and Rh; stoichiometric B2 ternary A (BxC1-x) alloys; and alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; the second group comprises: oxides of Ti, Mg, Ni, Zn, or Zr; and X—N or X—C composites where X is one or more of Sc, Ti, V, Cr, Zr, Nb, Ta, Hf, and W; and the third group comprises: tetragonal oxides with a-axis lattice parameters in a range of 4.35 Å to 4.75 Å and c-axis in the range of 2.85 Å to 3.19 Å; MO2, where M is Ti, Cr, Ru, Rh, Sn, Sb, or Ir; and CrNb, CrV, and WV alloys, and a ferromagnetic (FM) layer disposed on the interlayer.

The first and second migration barrier layers are each individually doped and laminated with a material of the TI or TSM layer. The TI or TSM layer comprises YPtBi having a (100) orientation or BiSb having a (012) orientation, and wherein the first and second migration barrier layers each individually comprise one or more materials selected from the first group or the third group. The TI or TSM layer comprises YPtBi having a (110) orientation, and wherein the first and second migration barrier layers each individually comprise one or more materials selected from the second group or the third group. The TI or TSM layer comprises YPtBi (100), or YPtBi (110), or BiSb having a (012) orientation, and wherein the first and second migration barrier layers each individually comprise one or more materials selected from the third group. The SOT device further comprises a buffer layer, wherein the first migration barrier layer is disposed on the buffer layer. A magnetic recording head comprises the SOT device. A magnetic recording device comprises the magnetic recording head. A magneto-resistive memory comprises the SOT device.

In another embodiment, a spin-orbit torque (SOT) device comprises a ferromagnetic (FM) layer, an interlayer comprising a sub-interlayer disposed on the FM layer, and a first migration barrier layer disposed on the sub-interlayer, a topological insulator (TI) or topological semi-metal (TSM) layer disposed on the first migration barrier layer, and a second migration barrier layer disposed on the TI or TSM layer, the first and second migration barrier layers each individually comprising one or more materials selected from a first group, a second group, or a third group, wherein: the first group comprises: RuHf; Zr—X alloys, where X is one or more of Co, Cu, Ru, and Rh; Ti—Y alloys, where Y is one or more of Au, Ru, and Rh; stoichiometric B2 ternary A (BxC1-x) alloys; and alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; the second group comprises: oxides of Ti, Mg, Ni, Zn, or Zr; and X—N or X—C composites where X is one or more of Sc, Ti, V, Cr, Zr, Nb, Ta, Hf, and W; and the third group comprises: tetragonal oxides with a-axis lattice parameters in a range of 4.35 Å to 4.75 Å and c-axis in the range of 2.85 Å to 3.19 Å; MO2, where M is Ti, Cr, Ru, Rh, Sn, Sb, or Ir; and CrNb, CrV, and WV alloys.

The TI or TSM layer comprises YPtBi having a (100) orientation or BiSb having a (012) orientation, and wherein the first and second migration barrier layers each individually comprise one or more materials selected from the first group or the third group. The TI or TSM layer comprises YPtBi having a (110) orientation, and wherein the first and second migration barrier layers each individually comprise one or more materials selected from the second group or the third group. The first and second migration barrier layers each individually has a thickness of about 4 Å to about 20 Å. The sub-interlayer has a (100) orientation, a (110) orientation, or a (012) orientation, and wherein the (100) orientation, a (110) orientation, or a (012) orientation of the sub-interlayer transfers through the first migration barrier layer to the TI or TSM layer. The SOT device further comprises a buffer layer disposed on the TI or TSM layer. A magnetic recording head comprises the SOT device. A magnetic recording device comprises the magnetic recording head. A magneto-resistive memory comprises the SOT device.

In yet another embodiment, a spin-orbit torque (SOT) device comprises a first migration barrier layer, a topological insulator (TI) or topological semi-metal (TSM) layer disposed in contact with the first migration barrier layer, the TI or TSM layer comprising YPtBi having a (100) orientation, YPtBi having a (110) orientation, or BiSb having a (012) orientation, a second migration barrier layer disposed in contact with the TI or TSM layer, the first and second migration barrier layers each individually comprising one or more materials selected from a first group, a second group, or a third group, wherein: the first group comprises: RuHf; Zr—X alloys, where X is one or more of Co, Cu, Ru, and Rh; Ti—Y alloys, where Y is one or more of Au, Ru, and Rh; stoichiometric B2 ternary A (BxC1-x) alloys; and alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; the second group comprises: oxides of Ti, Mg, Ni, Zn, or Zr; and X—N or X—C composites where X is one or more of Sc, Ti, V, Cr, Zr, Nb, Ta, Hf, and W; and the third group comprises: tetragonal oxides with a-axis lattice parameters in a range of 4.35 Å to 4.75 Å and c-axis in the range of 2.85 Å to 3.19 Å; MO2, where M is Ti, Cr, Ru, Rh, Sn, Sb, or Ir; and CrNb, CrV, and WV alloys, and a ferromagnetic (FM) layer.

The SOT device further comprises a buffer layer and an interlayer, wherein the first migration barrier layer is disposed on the buffer layer, the interlayer is disposed on the second migration barrier layer, and the FM layer is disposed on the interlayer. The SOT device further comprises a buffer layer and an interlayer, wherein the interlayer is disposed on the FM layer, the first migration barrier layer is disposed on the interlayer, and the buffer layer is disposed on the second migration barrier layer. The first and second migration barrier layers are each individually doped with a material of the TI or TSM layer. A magnetic recording head comprises the SOT device. A magnetic recording device comprises the magnetic recording head. A magneto-resistive memory comprises the SOT device.

While the foregoing is directed to embodiments of the present disclosure, other and further embodiments of the disclosure may be devised without departing from the basic scope thereof, and the scope thereof is determined by the claims that follow.

What is claimed is:

1. A spin-orbit torque (SOT) device, comprising:
a first migration barrier layer;
a topological insulator (TI) or topological semi-metal (TSM) layer disposed on the first migration barrier layer;
a second migration barrier layer disposed on the TI or TSM layer, wherein the first and second migration barrier layers each individually comprising one or more materials selected from a first group, a second group, or a third group, wherein:
the first group comprises:
RuHf;
Zr—X alloys, where X is one or more of Co, Cu, Ru, and Rh;
Ti—Y alloys, where Y is one or more of Au, Ru, and Rh;
stoichiometric B2 ternary A (BxC1-x) alloys; and
alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag;
the second group comprises:
oxides of Ti, Mg, Ni, Zn, or Zr; and
X—N or X—C composites where X is one or more of Sc, Ti, V, Cr, Zr, Nb, Ta, Hf, and W; and
the third group comprises:
tetragonal oxides with a-axis lattice parameters in a range of 4.35 Å to 4.75 Å and c-axis in the range of 2.85 Å to 3.19 Å;
MO₂, where M is Ti, Cr, Ru, Rh, Sn, Sb, or Ir; and
CrNb, CrV, and WV alloys;
an interlayer disposed on the second migration barrier layer; and
a ferromagnetic (FM) layer disposed on the interlayer.

2. The SOT device of claim 1, wherein the first and second migration barrier layers are each individually doped with a material of the TI or TSM layer.

3. The SOT device of claim 1, wherein the TI or TSM layer comprises YPtBi having a (100) orientation or BiSb having a (012) orientation, and wherein the first and second migration barrier layers each individually comprise one or more materials selected from the first group or the third group.

4. The SOT device of claim 1, wherein the TI or TSM layer comprises YPtBi having a (110) orientation, and wherein the first and second migration barrier layers each individually comprise one or more materials selected from the second group or the third group.

5. The SOT device of claim 1, wherein the TI or TSM layer comprises YPtBi (100), or YPtBi (110), or BiSb having a (012) orientation.

6. The SOT device of claim 5, wherein the first and second migration barrier layers each individually comprise one or more materials selected from the third group.

7. The SOT device of claim 1, further comprising a buffer layer, wherein the first migration barrier layer is disposed on the buffer layer.

8. A magnetic recording head comprising the SOT device of claim 1.

9. A magnetic recording device comprising the magnetic recording head of claim 8.

10. A magneto-resistive memory comprising the SOT device of claim 1.

11. A spin-orbit torque (SOT) device, comprising:
a ferromagnetic (FM) layer;
an interlayer comprising a sub-interlayer disposed on the FM layer, and a first migration barrier layer disposed on the sub-interlayer;
a topological insulator (TI) or topological semi-metal (TSM) layer disposed on the first migration barrier layer; and
a second migration barrier layer disposed on the TI or TSM layer, the first and second migration barrier layers each individually comprising one or more materials selected from a first group, a second group, or a third group, wherein:
the first group comprises:
RuHf;
Zr—X alloys, where X is one or more of Co, Cu, Ru, and Rh;
Ti—Y alloys, where Y is one or more of Au, Ru, and Rh;
stoichiometric B2 ternary A (BxC1-x) alloys; and
alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag;
the second group comprises:
oxides of Ti, Mg, Ni, Zn, or Zr; and
X—N or X—C composites where X is one or more of Sc, Ti, V, Cr, Zr, Nb, Ta, Hf, and W; and
the third group comprises:
tetragonal oxides with a-axis lattice parameters in a range of 4.35 Å to 4.75 Å and c-axis in the range of 2.85 Å to 3.19 Å;
MO₂, where M is Ti, Cr, Ru, Rh, Sn, Sb, or Ir; and
CrNb, CrV, and WV alloys.

12. The SOT device of claim 11, wherein the TI or TSM layer comprises YPtBi having a (100) orientation or BiSb having a (012) orientation, and wherein the first and second migration barrier layers each individually comprise one or more materials selected from the first group or the third group.

13. The SOT device of claim 11, wherein the TI or TSM layer comprises YPtBi having a (110) orientation, and wherein the first and second migration barrier layers each individually comprise one or more materials selected from the second group or the third group.

14. The SOT device of claim 11, wherein the first and second migration barrier layers each individually has a thickness of about 4 Å to about 20 Å.

15. The SOT device of claim 11, wherein the sub-interlayer has a (100) orientation, a (110) orientation, or a (012) orientation, and wherein the (100) orientation, a (110) orientation, or a (012) orientation of the sub-interlayer transfers through the first migration barrier layer to the TI or TSM layer.

16. The SOT device of claim 11, further comprising a buffer layer disposed on the TI or TSM layer.

17. A magnetic recording head comprising the SOT device of claim 11.

18. A magnetic recording device comprising the magnetic recording head of claim 17.

19. A magneto-resistive memory comprising the SOT device of claim 11.

20. A spin-orbit torque (SOT) device, comprising:
a first migration barrier layer;
a topological insulator (TI) or topological semi-metal (TSM) layer disposed in contact with the first migration barrier layer, the TI layer comprising YPtBi having a (100) orientation, YPtBi having a (110) orientation, or BiSb having a (012) orientation;
a second migration barrier layer disposed in contact with the TI or TSM layer, the first and second migration barrier layers each individually comprising one or more materials selected from a first group, a second group, or a third group, wherein:
the first group comprises:
RuHf;
Zr—X alloys, where X is one or more of Co, Cu, Ru, and Rh;
Ti—Y alloys, where Y is one or more of Au, Ru, and Rh;
stoichiometric B2 ternary A (BxC1-x) alloys; and
alloys comprising multiple elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag;
the second group comprises:
oxides of Ti, Mg, Ni, Zn, or Zr; and
X—N or X—C composites where X is one or more of Sc, Ti, V, Cr, Zr, Nb, Ta, Hf, and W; and
the third group comprises:
tetragonal oxides with a-axis lattice parameters in a range of 4.35 Å to 4.75 Å and c-axis in the range of 2.85 Å to 3.19 Å;
MO₂, where M is Ti, Cr, Ru, Rh, Sn, Sb, or Ir; and
CrNb, CrV, and WV alloys; and
a ferromagnetic (FM) layer.

21. The SOT device of claim 20, further comprising a buffer layer and an interlayer, wherein the first migration barrier layer is disposed on the buffer layer, the interlayer is disposed on the second migration barrier layer, and the FM layer is disposed on the interlayer.

22. The SOT device of claim 20, further comprising a buffer layer and an interlayer, wherein the interlayer is disposed on the FM layer, the first migration barrier layer is disposed on the interlayer, and the buffer layer is disposed on the second migration barrier layer.

23. The SOT device of claim 20, wherein the first and second migration barrier layers are each individually doped with a material of the TI or TSM layer.

24. A magnetic recording head comprising the SOT device of claim 20.

25. A magnetic recording device comprising the magnetic recording head of claim 24.

26. A magneto-resistive memory comprising the SOT device of claim 20.
